(19) United States
(12) Patent Application Publication
(10) Pub. No.: US 2011/0005569 A1
(43) Pub. Date: Jan. 13, 2011

(54) PARALLEL INTERCONNECTION OF SOLAR CELL UNITS

(75) Inventors: Erik Sauar, Oslo (NO); Eckehard Hofmüller, Oslo (NO)

Correspondence Address: BIRCH STEWART KOLASCH & BIRCH, PO BOX 747, FALLS CHURCH, VA, 22040-0747, US

(73) Assignee: Renewable Energy Corporation ASA, Hovik (NO)

(21) Appl. No.: 12/738,014

(22) PCT Filed: Oct. 15, 2008
(86) PCT No.: PCT/NO2008/000367

§ 371 Date: Sep. 23, 2010

(30) Foreign Application Priority Data
Oct. 16, 2007 (GB) 0720216.1

(51) Int. Cl. H01L 31/048; H01L 31/04; H01L 31/042; B23K 1/20; B23K 31/02

(52) U.S. Cl. 136/244; 136/252; 136/256; 228/246; 228/176

(57) ABSTRACT

Method for manufacturing an solar cell device, characterized in that the method comprises among others the following steps: arranging solar cell units (1) and electrically insulating units (2) alternatingly next to each other; applying rear soldering ribbons (3) to the rear side of the solar cell units (1) and the electrically insulating units (2); applying front soldering ribbons (4) to the front side of the solar cell units (1) and the electrically insulating units (2); soldering the rear soldering ribbons (3) and the front soldering ribbons (4) to the solar cell units (1), thereby providing an assembled solar cell. The invention also comprises a solar cell manufactured by means of the method.

### FIELD OF THE INVENTION

The present invention relates to a method for manufacturing of solar cells.

### BACKGROUND OF THE INVENTION

A conventional solar cell module comprises several interconnected silicon solar cells—each cell made from one wafer. FIG. 1 shows prior art, where two solar cells are connected in series by means of soldering ribbons.

For certain low concentration module technologies, however, there is a large benefit from splitting/cutting the cells into smaller, but preferably longer rectangular units and then introducing a spacing between these cell units. The cell units can thereafter be interconnected either in series or in parallel.

The electrical parameters for each cell unit are measured during the manufacturing process because of quality requirements. Hence, the costs related to the quality control increase proportionally with the number of cell units made from a wafer.

Moreover, the soldering process requires that a soldering wire is cut and soldered for each cell unit. As the number of cell units per wafer increases, there is a considerable decrease in the efficiency of the soldering machines.

One object of the present invention is to provide a method for parallel interconnection of solar cell units where the number of cell units on a wafer can be increased without the above disadvantage. A second object is to reduce the costs related to the quality control of the cell units. A third object is that the module voltage level should be at the same level as conventional modules.

### SUMMARY OF THE INVENTION

To address the above mentioned problems and achieve the abovementioned objects, the invention comprises a method for manufacturing a solar cell, characterized in that the method comprises the following steps:

arranging solar cell units and electrically insulating units alternatingly next to each other;

applying rear soldering ribbons to the rear side of the solar cell units and the electrically insulating units;

applying front soldering ribbons to the front side of the solar cell units and the electrically insulating units;

soldering the rear soldering ribbons and the front soldering ribbons to the solar cell units, thereby providing an assembled solar cell.

The invention comprises also a solar cell device comprising

an assembly of solar cell units (1) and electrically insulating units (2) arranged alternatingly next to each other;

rear soldering ribbons (3) applied to the rear side of the solar cell units (1) and the electrically insulating units (2);

front soldering ribbons (4) applied to the front side of the solar cell units (1) and the electrically insulating units (2);

where the rear soldering ribbons (3) and the front soldering ribbons (4) are soldered to the solar cell units (1), thereby providing an assembled solar cell device.

In one embodiment of the invention the front soldering ribbon (4) continues past the last solar cell unit (1) to form a rear soldering ribbon for a next assembled solar cell.

In one embodiment, the method comprises applying a transparent cover over the assembled solar cell or a plurality of assembled solar cells. In another embodiment the electrically insulating units (2) comprise a reflective surface.

In one embodiment of the invention the electrically insulating units extend over parts of the rear sides of the solar cell units.

In one embodiment of the invention the electrically insulating units comprise materials typically used as rear sheets for solar modules, e.g. combinations of PVF, PVDF and PET.

In one embodiment of the invention the length L of the electrically insulating units (2) is in the range of 2-5 times the thickness of the transparent cover.

Although different features of the invention have been mentioned in relation to different embodiments, it will be clear that embodiments comprising different combinations of these features belong to the scope of the invention as described in the independent claims.

### BRIEF DESCRIPTION OF THE DRAWINGS

In the following description of preferred embodiments of the invention, it will be referred to the drawings, where:

FIG. 1 illustrates a cross sectional view of two serially connected solar cells according to prior art;

FIG. 2 illustrates a cross sectional view of interconnected solar cell units according to the present invention

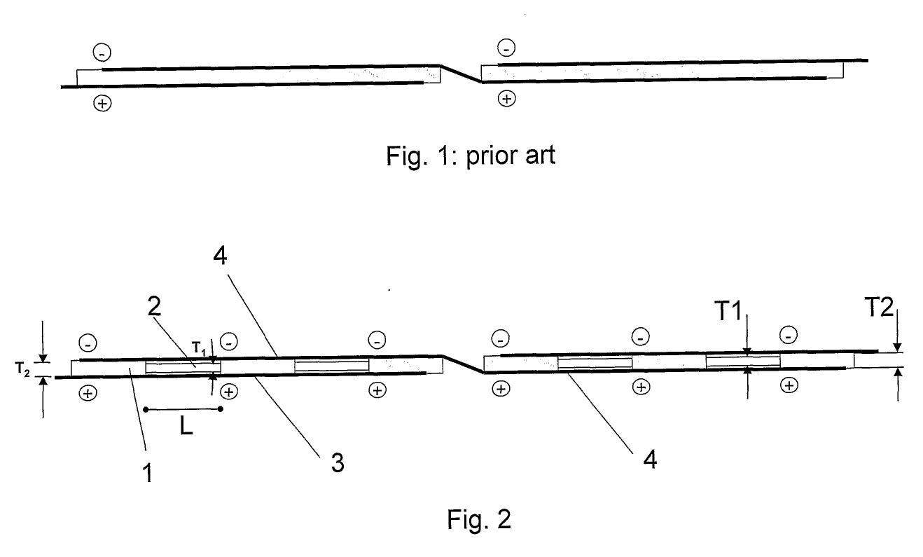

### DETAILED DESCRIPTION

It is now referred to FIG. 2.

First, a solar cell is divided into two or more solar cell units 1. The solar cell is for example divided into several elongated solar cell units 1 having a rectangular shape, but may have any other suitable form. The division can be performed by cutting, splitting, sawing or other suitable method.

In a next step a number of solar cell units 1 will be parallel interconnected whereby a certain spacing between the solar cell units 1 will be ensured. This number of parallel interconnected solar cell units will be hereafter called an assembled cell or a so-called supercell.

Rear soldering ribbons 3 for the back contact are first placed on a substantially planar surface. In practice the substantially planar surface would be a transportation belt or a working station in the production facility.

A number N solar cell units 1 together with N-1 electrically insulating units 2 are placed alternating along and on top of the rear soldering ribbons 3 until they together create a suitable length, for example approximately 150 mm, as shown in FIG. 2. In FIG. 2, it is shown that one supercell comprises N=3 solar cell units 1. In practice, the number N can vary from 2 to over 20. Front soldering ribbons 4 for the front contact are then placed on the front side (the upper side in FIG. 2) of cell units 1 and the electrically insulating units 2. The soldering ribbons for the front and the back contacts are then soldered to the cell units 1. Note that the front soldering ribbons 4 for the front contact continue past the last cell unit to form the soldering ribbons for the back contact of the next assembled cell or supercell.

Thereafter, a number of supercells may be processed further to a photovoltaic module as known by interconnecting and encapsulating the supercells behind a transparent cover (not shown).

Preferably, the spacing L between the solar cell units 1 is 2-5 times as long as the thickness of the transparent cover. In this embodiment of the invention the spacing L is equal to the length L of the electrically insulating units 2. This is related to the maximum light travel length in a low concentrating photovoltaic module utilizing the total internal reflection of incident sunlight reflected on a reflective structure in between the cells. The electrically insulating units 2 prevent the soldering ribbons for the front and for the back contacts from touching each other in the spacings between the solar cell units 2 and thus from short cutting the supercell. The thickness T1 of the electric insulating units 2 should preferably not exceed the thickness T2 of the solar cell units 1.

The electrically insulating units 2 can be any type of material that is electric insulating, preferably the material comprises materials typically used as back sheets for solar modules, for example combinations of PVF (polyvinylfluoride), PVDF (polyvinylidenfluoride) and PET (polyetylenterephthalate).

The electrically insulating units 2 may comprise a reflective structure or layer, to redirect incident sun light towards the adjacent solar cell units. In this way a good amount of silicon may be saved per module maintaining nearly the same power output.

According to the invention it is achieved a method where solar cell units can be interconnected parallel to supercells and these again interconnected in series in such a way that:

a significant amount of silicon solar cells may be saved per module and replaced by a reflective structure maintaining nearly the same power output compared to a conventional module.

the module voltage can remain substantially at the same level as conventional modules, because the number of series interconnected supercells may be the same as the number of series interconnected solar cells in a conventional module.

the electrical measurement of each solar cell unit is not necessary since they are again parallel interconnected as a supercell which replaces the conventional solar cell.

production rate for interconnection machines (measured in sqm/time) is not substantially reduced compared to standard modules since a supercell may be handled in a same way as a solar sell by such a machine.

1. Method for manufacturing a solar cell, wherein the method comprises the following steps:
arranging solar cell units and electrically insulating units alternatingly next to each other;
applying rear soldering ribbons to the rear side of the solar cell units and the electrically insulating units;
applying front soldering ribbons to the front side of the solar cell units and the electrically insulating units;
soldering the rear soldering ribbons and the front soldering ribbons to the solar cell units, thereby providing an assembled solar cell.

2. Method according to claim 1, wherein the front soldering ribbon continues past the last solar cell unit to form a rear soldering ribbon for a next assembled solar cell.

3. Method according to claim 1, wherein applying a transparent cover over the assembled solar cell or a plurality of assembled solar cells.

4. Method according to claim 1, wherein the electrically insulating units comprise a reflective surface.

5. Method according to claim 1, wherein the electrically insulating units extend over parts of the rear sides of the solar cell units.

6. Method according to claim 1, wherein the electrically insulating units comprise materials typically used as rear sheets for solar modules, e.g. combinations of PVF, PVDF and PET.

7. Method according to claim 3, wherein the length L of the electrically insulating units is in the range of 2-5 times the thickness of the transparent cover.

8. Solar cell device, wherein it comprises:
an assembly of solar cell units and electrically insulating units arranged alternatingly next to each other;
rear soldering ribbons applied to the rear side of the solar cell units and the electrically insulating units;
front soldering ribbons applied to the front side of the solar cell units and the electrically insulating units;
where the rear soldering ribbons and the front soldering ribbons are soldered to the solar cell units, thereby providing an assembled solar cell device.

9. Device according to claim 8, wherein the front soldering ribbon is continued past the last solar cell unit to form a rear soldering ribbon for a next assembled solar cell.

10. Device according to claim 8, wherein a transparent cover is provided over the assembled solar cell or a plurality of assembled solar cells.

11. Device according to claim 8, wherein the electrically insulating units comprises a reflective surface.

12. Device according to claim 8, wherein the electrically insulating units extend over parts of the rear sides of the solar cell units.

13. Device according to claim 8, wherein the electrically insulating units comprise materials typically used as rear sheets for solar modules, e.g. combinations of PVF, PVDF and PET.

14. Device according to claim 10, wherein the length L of the electrically insulating units is in the range of 2-5 times the thickness of the transparent cover.

15. Method according to claim 2, wherein applying a transparent cover over the assembled solar cell or a plurality of assembled solar cells.

16. Method according to claim 2, wherein the electrically insulating units comprise a reflective surface.

17. Method according to claim 3, wherein the electrically insulating units comprise a reflective surface.

18. Method according to claim 2, wherein the electrically insulating units extend over parts of the rear sides of the solar cell units.

19. Method according to claim 3, wherein the electrically insulating units extend over parts of the rear sides of the solar cell units.

20. Method according to claim 4, wherein the electrically insulating units extend over parts of the rear sides of the solar cell units.
